(19) United States
(12) Patent Application Publication
(10) Pub. No.: US 2007/0202699 A1
(43) Pub. Date: Aug. 30, 2007

(54) Electronic component fabrication method

(75) Inventors: Hiroshi Toyoda, Kanagawa (JP); Masahiko Hasunuma, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/710,477

(22) Filed: Feb. 26, 2007

(30) Foreign Application Priority Data
Feb. 27, 2006 (JP) 2006-049523

(51) Int. Cl. H01L 21/44

(52) U.S. Cl. 438/687; 438/654

(57) ABSTRACT

A method for fabricating an electronic component, includes forming a seed film above a base body, cooling said seed film, and putting the cooled seed film into a plating solution to perform electro-plating with said seed film being as a cathode.

### CROSS-REFERENCE TO RELATED APPLICATION

This application is based upon and claims priority from Japanese Patent Application No. 2006-049523, filed Feb. 27, 2006, the entire contents of which are incorporated herein by reference.

### BACKGROUND OF THE INVENTION

1. Field of the Invention

The present invention relates generally to a method for manufacturing electronic components and, more particularly to a semiconductor device fabrication method including the formation of damascene interconnect wires made of a copper (Cu) formed by electro-plating on a Cu seed film that lies above a silicon substrate or wafer.

2. Description of the Related Art

Higher integration and performance requirements for large-scale integrated (LSI) semiconductor circuit devices in recent years result in development of new microfabrication technologies. In particular, one of today's trends is to change electrical interconnect wire material from traditionally used aluminum (Al) alloys to the lower resistivity metal-based materials—typically, pure copper (Cu), Cu alloys or Cu-containing materials. These Cu-based materials are inherently difficult in microfabrication processing by means of dry etch techniques, such as reactive ion etching (RIE) as has been used in the formation of Al alloy wires. To break through this difficulty, the so-called damascene process is mainly employed, which has the steps of depositing a Cu film on a dielectric film with grooves or trenches defined therein, and using chemical-mechanical polishing (CMP) to remove dielectric film portions other than those as filled in the trenches to thereby form buried wires. A usual approach to forming a Cu film is to employ a process of forming a thin Cu seed film by sputtering and, thereafter, forming by electro-plating a multilayered film with a thickness of about several hundred of nanometer (nm). In the case of a multilayered Cu interconnect wires being fabricated, what is called the dual damascene technique is also employable. This buried wire forming technique is as follows. First, form an electrically insulative film on an underlying wire layer on a substrate. Then, define therein openings called the via holes and trench grooves for the upper layer wire use. Thereafter, bury a Cu wire material in the via holes and the trenches at a time. Next, apply CMP to remove away unnecessary portions of Cu on the top surface to fabricate resultant device structure, thereby to form a pattern of buried interconnect wires.

For an interlayer dielectric (ILD) film to be used in such the structure, it is under consideration to use a film made of specific insulative material having a low dielectric constant k—called the “low-k” material. More specifically, an attempt is made to replace the currently used silicon oxide (SiO₂) film having its relative dielectric constant k of about 3.9 by a low-k film with its relative dielectric constant of 3.0 or below, thereby to reduce the parasitic capacitance between adjacent ones of on-chip interconnect wires.

Recall here that a Cu seed film formed by sputtering is appreciably less in thickness of its sidewall portions and thus is readily soluble with plating solution. Once such plating-solved or “fused” portions take place in the Cu seed film, no further Cu films are formable on these portions. This can be said because any electrical current does not flow therein even electro-plating is applied thereto. For this reason, even where such fused portions are completely buried with another Cu film that was grown from the surroundings, such portions remain less in adhesivity between the sidewall and Cu film, resulting in defect generation. One approach to avoiding this problem is disclosed, for example, in Published Unexamined Japanese Patent Application (“PUJPA”) No. 2004-218080. With the process as taught thereby, a Cu seed film-formed substrate is dipped into a plating solution while applying thereto a voltage which is the same as that used during plating. Dipping with such voltage application prevents unwanted dissolution of the Cu seed film.

Unfortunately, the advantage of this prior known method does not come without accompanying a penalty as to degradation of the uniformity of buried Cu film. More specifically, while it is required to set the application voltage at a specific potential level which permits occurrence of Cu plating in order to completely prevent the Cu seed film's dissolution, a certain length of time is needed for the entire surface of substrate dipped in a plating bath to be fully wetted by a plating solution in the bath so that a difference in plating time occurs between a portion that was first wetted by the solution and a portion as last wetted thereby, resulting in a decrease in uniformity of the buried thickness of a Cu film that was grown by plating on the substrate surface. To avoid this problem, the lower voltage may be applied to the substrate. However, this poses another problem: deposition failures and defects can occur at thin sidewall portions of the Cu seed film.

### BRIEF SUMMARY OF THE INVENTION

In accordance with one aspect of this invention, a method for fabricating an electronic component, includes forming a seed film above a base body, cooling said seed film, and putting the cooled seed film into a plating solution to perform electro-plating with said seed film being as a cathode.

In accordance with another aspect of the invention, a method for fabricating an electronic component, includes forming an opening in a base body, burying a copper-containing film in the opening, and permitting additional deposition of said copper-containing film above said base body with the opening filled with said copper-containing film while cooling said base body.

### BRIEF DESCRIPTION OF THE DRAWINGS

FIG. 1 is a flow chart showing main steps of a fabrication method of a semiconductor device in accordance with an embodiment of this invention.

FIGS. 2A-2C and 3A-3C illustrate, in cross section, some major steps in the manufacture of the semiconductor device in a way corresponding to the flowchart of FIG. 1.

FIG. 4 is a diagram showing one example of a plating apparatus for use with the embodiment method shown in FIG. 1, in the state that a substrate is situated at a waiting position.

FIG. 5 is a diagram showing another example of the plating apparatus with the substrate being held at a plating position in the embodiment.

FIG. 6 depicts in cross-section a device structure as formed at a process step of the embodiment method of FIG. 1.

FIG. 7 shows a cross-sectional device structure with a seed film formed on its top surface in the embodiment.

FIGS. 8A and 8B are diagrams each showing a cross-section of the substrate for explanation of a substrate-cooling effect of the embodiment.

FIGS. 9A and 9B are diagrams showing one example of a substrate-entry scheme in another embodiment of the invention.

FIG. 10 is a graph showing a plot of current density versus varying voltage in steps during plating with multiple current density values.

### DETAILED DESCRIPTION OF THE INVENTION

### Embodiment 1

A fabrication method of a semiconductor device which is an example of electronic component in accordance with one embodiment of this invention will be described. In this embodiment, a pattern of Cu interconnect wires with the damascene structure are formed on a low-dielectric-constant or “low-k” insulative film in a way as will be explained with reference to some of the accompanying drawings below.

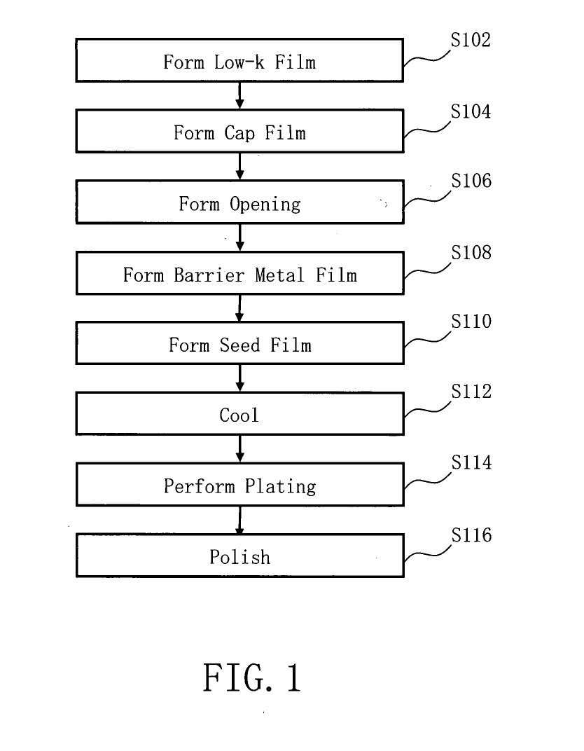

Referring to FIG. 1, there is shown in flow diagram from main steps of a semiconductor device fabrication method in accordance with the embodiment of this invention. As shown herein, this embodiment method is arranged to perform a series of processes which follow. At step S102, form a low-k thin-film made of a chosen dielectric material having a low relative dielectric constant k. At step S104, form a cap film. In step S106, define in the film a predetermined number of interlevel openings, called the trench or the via holes. Then, at step S108, form a conductive material film—here, a barrier metal film. Next at step S110, form a seed film, followed by cooling at step S112, plating at step S114, and polishing at step S116.

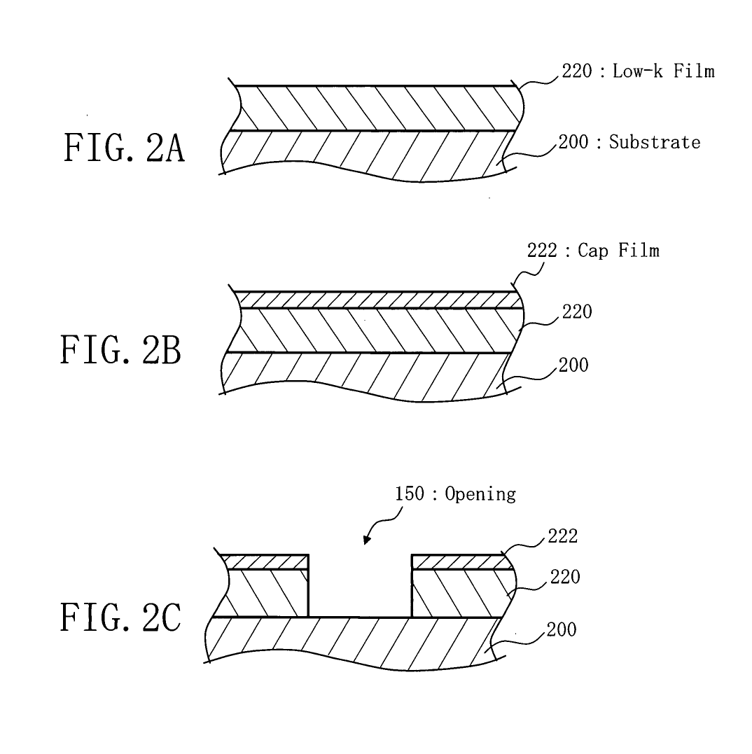

Cross-sectional views of a semiconductor device structure as obtained at the steps S102 to S106 of FIG. 1 are illustrated in FIGS. 2A to 2C, respectively.

As shown in FIG. 2A, at the step S102 of FIG. 1, a low-k film 220 made of a chosen porous low-dielectric-constant insulative material is formed on a substrate 200 which is an example of a base body, to a predetermined thickness of about 200 nanometers (nm). The substrate 200 is illustratively a semiconductor substrate. Forming this low-k film 220 is aimed at fabrication of an interlayer dielectric (ILD) film having its relative dielectric constant k being less than or equal to 3.0. An example of the ILD film material is polymethylsiloxane-based low-k dielectric material with its relative dielectric constant of less than 2.5. Other examples of it are a film having siloxane backbone structures such as polysiloxane, hydrogen silsesquioxane and methylsilsesquioxane, a film containing as its main component an organic resin such as polyarylene ether, polybenzoxazole or polybenzocyclobutene, and a porous film such as a porous silica film. Using any one of these materials enables the low-k film 220 to have the relative dielectric constant of less than 2.5. An exemplary approach to forming such film is to use the so-called spin-on-dielectric (SOD) coating technique which forms a thin film through spin coating of a liquid solution and thermal processing applied thereto. For instance, the film fabrication is realizable in a way such that a wafer with a film being formed thereon by a spinner is baked on a hot plate in a nitrogen-containing atmosphere and is finally subjected to curing on the hot plate at temperatures higher than the baking temperature. By appropriate choice of the low-k material and adequate adjustment of film formation process conditions, it is possible to obtain the intended porous dielectric thin film having a prespecified physical value(s). Additionally, an example of the substrate 200 is a silicon wafer having its diameter of 300 millimeters (mm). Note here that an explanation is omitted as to the formation of on-chip circuit elements or devices, which are positioned at lower layers of the low-k film 220.

Then, as shown in FIG. 2B, at the step S104 of FIG. 1, a dielectric cap film 222 is chemically vapor-deposited on the low-k film 220 to a thickness of 50 nm, for example. The cap film 222 may typically be made of silicon oxycarbide (SiOC). Forming the SiOC cap film 222 makes it possible to protect its underlying low-k film 220 that has difficulties in direct application of lithography, and thus enables formation of a pattern in the low-k film 220. Examples of the cap insulator film material other than SiOC are dielectric materials with a relative dielectric constant of 2.5 or greater, as selected from the group consisting essentially of silicon oxide (SiO₂), SiC, silicon carbohydride (SiCH), silicon carbonitride (SiCN), and SiOCH. Although the film fabrication here is performed by CVD, other similar suitable techniques are alternatively employable.

Next, as shown in FIG. 2C, at the opening forming step S106, through-going openings 150 for use as a wiring groove structure for damascene wire fabrication are defined by lithography and dry etching techniques in the SiOC cap film 222 and low-k film 220. For the substrate 200 with a resist film being formed on the SiOC cap film 222 through resist deposition and lithography processes such as exposure (not shown), the exposed SiOC cap film 222 and its underlying low-k film 220 are selectively removed away by anisotropic etching techniques, thereby making it possible to form the opening 150 substantially vertically with respect to the surface of substrate 200. For example, the opening 150 may be formed by a reactive ion etching (RIE) method.

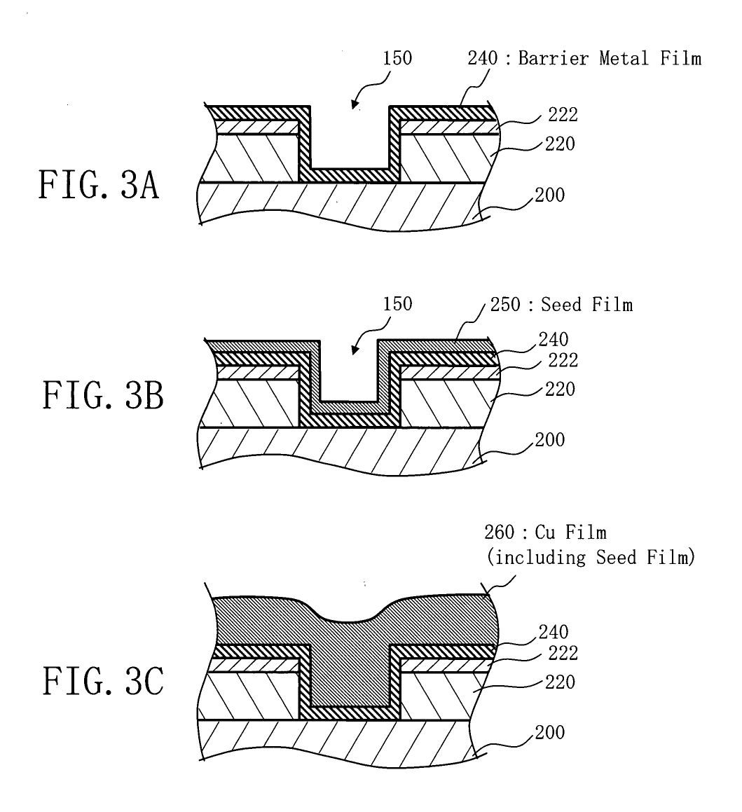

Sectional device structures obtained at the steps S108-S114 of FIG. 1 are depicted in FIGS. 3A-3C, respectively.

In FIG. 3A, at the barrier metal film forming step S108, a barrier metal film 240 which is made of a chosen barrier metal material is formed in the opening 150 that was defined by the opening forming process and also on a top surface of the SiOC cap film 222. Within a sputtering apparatus using a sputter technique which is one of physical vapor deposition (PVD) methods, a thin film of tantalum (Ta) is deposited to a thickness of 5 nm for example, thereby forming the barrier metal film 240. The deposition of the barrier metal material is achievable not only by PVD but also by atomic layer deposition (ALD) or CVD such as atomic layer chemical vapor deposition (ALCVD). Using these methods makes it possible to improve the film coverage ratio when compared to that in the case of using PVD methods. Additionally the material of the barrier metal film is not exclusively limited to Ta and may alternatively be made of a tantalum-containing material such as tantalum nitride (TaN), a titanium-containing material such as titanium (Ti) or titanium nitride (TiN), or a tungsten-containing material such as tungsten nitride (WN). The film may be a multilayer film made of more than two of these materials in combination, such as Ta and TaN or the like.

In FIG. 3B, at the seed film forming step S110, a Cu thin film is deposited (formed) as a seed film 250 (one example of the copper-containing film) by PVD, such as sputtering or else, on the inner wall of the opening 150 with the barrier metal film 240 formed thereon and also on the surface of substrate 200. This thin film will become a cathode electrode in an electro-plating process to be next performed. Here, the seed film 250 is formed to have a thickness of 45 nm, for example. Deposition of film thickness of 45 nm on the surface of substrate 200 results in a thickness on sidewall of opening 150 becoming 10 nm or less and in the minimum film thickness being 3 nm or below, although this value is variable depending on the diameter of opening 150.

Here, in this embodiment, a cooling process is performed to prevent the seed film 250 from disappearing due to unwanted dissolution into the plating solution. That is, at the step S112, get the seed film 250 cooled. More specifically, use a chosen gas to cool the back surface of substrate 200 to thereby cool seed film 250 through this substrate back surface.

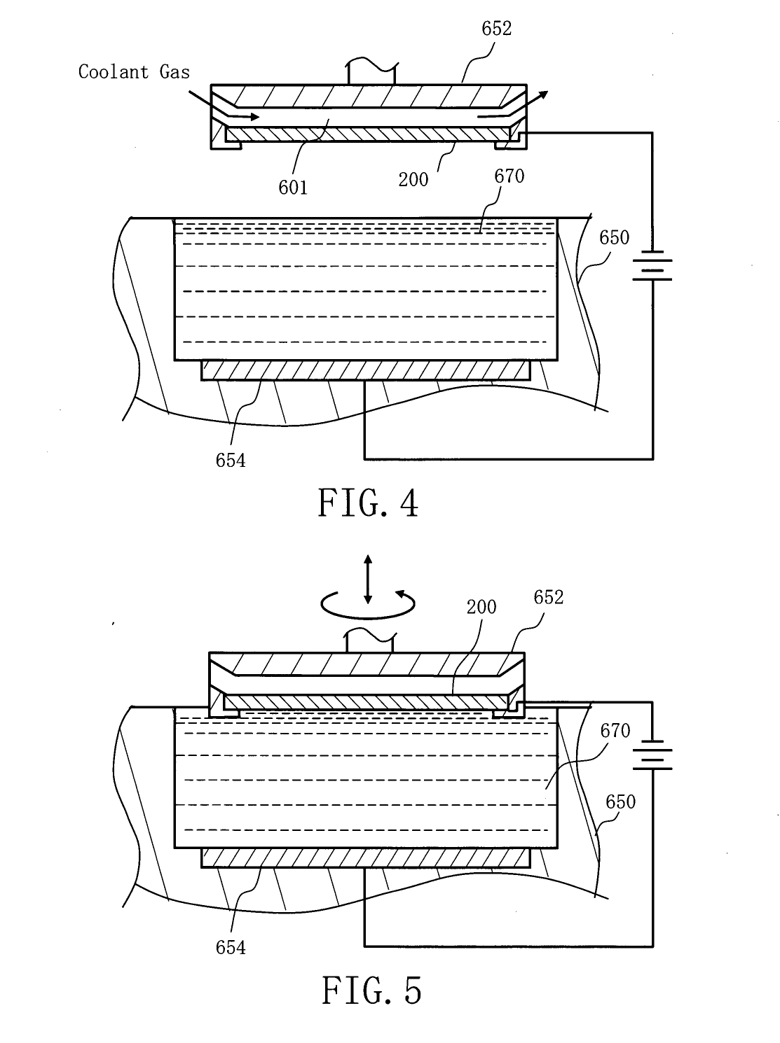

An exemplary structure of a plating apparatus with a substrate being held at a waiting position in this embodiment is schematically shown in FIG. 4. This plating tool has an almost cylindrical plating vessel or “bath” 650 that contains therein a plating solution 670, and a holder 652 which is disposed above the plating bath 650 for detachably holding the substrate 200 with its plating surface being directed to the downward direction. Preferably the plating solution 670 is a copper sulfate-based solution with an additive blended thereinto. The plating bath 650 has its bottom on which an anode electrode 654 is disposed so that its upper surface is exposed to the plating solution 670. An example of the anode electrode 654 is a dissoluble anode made of phosphorus-containing copper. The plating solution 670 is supplied from a spraying nozzle (not shown), which is coupled to the interior space of plating bath 650. An extra part of the plating solution 670 as over-flown from plating bath 650 is drained from an exhaust port (not shown). These exhaust port and liquid spray nozzle are coupled to a plating solution management device (not shown), which causes the drained plating solution 670 to undergo chemical component adjustment for return to the interior of plating bath 650, followed by liquid circulation along this route. During circulation, the plating solution 670 is temperature-controlled by the manager device to stay at a prespecified temperature—e.g., 25° C.

In FIG. 4, a state is shown wherein the holder 652 holds the substrate 200 at a position as raised up from the surface of the plating solution 670. For example, the substrate 200 is held at a waiting position for transfer using a robot arm (not shown). An electrical contact on the cathode side is connected to an outer peripheral part of the surface of the seed film-formed substrate 200 in a region which is in noncontact with the plating solution 670. An anode-side contact is connected to the anode electrode 654. The holder 652 is machined so that a space is formed on its back surface side, which space is for use as a gas flow path or channel 601. A coolant gas with a desired low temperature is guided to flow on the back surface of the substrate 200 being held at the waiting position, thereby to control the substrate temperature. Examples of the coolant gas are a nitrogen gas and atmospheric air. A silicon wafer which is an example of the substrate 200 is excellent in thermal conductivity, so it is possible by forcing such gas to flow on the back surface of substrate 200 for a sufficient length of time to allow the substrate temperature to be substantially the same as the gas temperature.

Desirably, the substrate cooling is carried out so that the substrate temperature is lower by at least 10 degrees than the temperature of the plating solution 670. An example is that when the plating solution 670 is 25° C. in its temperature, the substrate temperature is controlled to fall within a range of from 5 to 15° C., wherein at the former temperature the substrate 200 does not exhibit moisture condensation. In case the seed film 250's dissolving rate in the 25° C.-plating solution 670 is 100%, setting the substrate temperature at 15° C. makes it possible to suppress the dissolution rate of seed film 250 in plating solution 670 down to 56%, or more or less. Alternatively, setting the substrate temperature at 5° C. enables the dissolution rate of seed film 250 in plating solution 670 to be lowered to about 30%. In short, by letting the substrate temperature be 15° C. or below, it is possible to delay by nearly half the rate of dissolution. Preferably the cooling position is as close to the plating solution 670 as possible. By doing so, a time taken for the substrate 200 to come into contact with the plating solution 670 becomes shorter, thereby enabling conservation of the intended cooling effect.

In FIG. 3C, at the plating step S114, an electrochemical growth method based on electro-plating is used to deposit, with the seed film 250 being as the cathode electrode, a thin Cu film 260 (one example of the copper-containing film) in the opening 150 and on the surface of substrate 200. Here, the Cu film 260 is deposited to a thickness of 800 nm as an example. After completion of the deposition, annealing is performed at a temperature of 250° C. for 30 minutes, for example.

A structure of plating tool with the substrate being situated at a plating position is shown in FIG. 5. In this embodiment, when entering the surface of substrate 200 into the plating bath 650 with the plating solution 670 stored therein, the substrate 200 having the seed film 250 being cooled at the above-noted cooling step S112 is driven to rotate. The rotating substrate surface is then dipped into the plating solution 670. Then, an electrical current of a prespecified current density is flown with the anode electrode 654 and the seed film 250 on substrate 200, which becomes the to-be-plated surface, as the cathode electrode, thereby performing electro-plating. At this time it is more preferable for the substrate 200 to enter into the plating solution 670 in an angled or tilted state to ensure that no air bubbles reside between substrate 200 and plating solution 670. Also preferably, a voltage is applied to the substrate 200 side that becomes the cathode when the need arises due to the thickness conditions of the seed film 250, as will be described later.

Then, CMP is applied to the resultant substrate structure to remove extra portions of the Cu film 260 and barrier metal film 240 as have been deposited in the opening 150, followed by the formation of damascene interconnect wires in a way which follows.

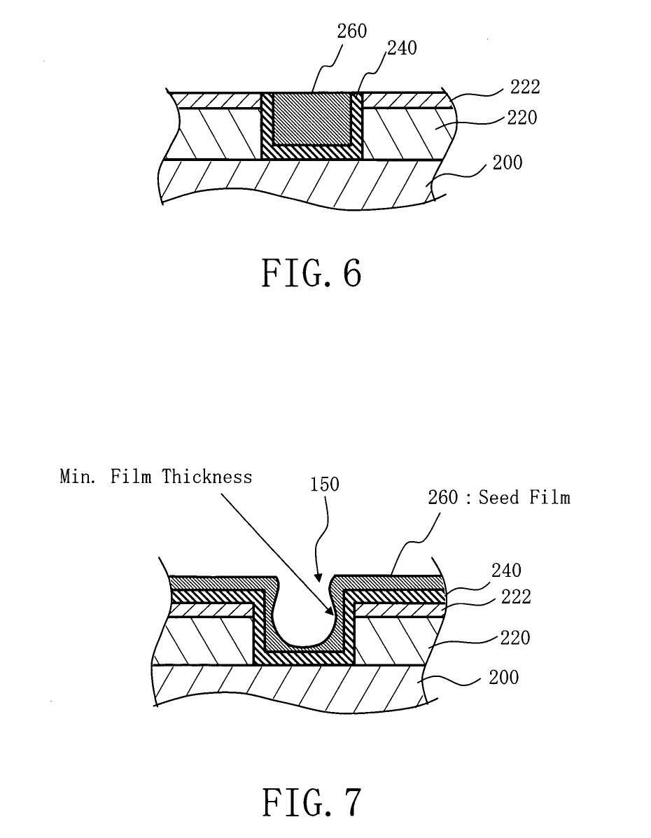

As shown in FIG. 6, at the polishing step S116, the top surface of resultant substrate 200 is polished by CMP to selectively remove those portions deposited on surface portions other than the opening 150 of the barrier metal film 240 and Cu film 260 including the seed film 250 which becomes a wiring layer as electrical conductor so that a surface-flattened or “planarized” structure is obtained with a pattern of damascene wires being formed.

A cross-sectional structure of the substrate 200 is shown in FIG. 7 in the state that the seed film 250 is formed thereon in this embodiment. When this seed film 250 is formed by sputtering or like techniques, this film becomes irregular in thickness on the inner sidewall of opening 150 and must have a concave portion with a minimal thickness. It has been found by experiment conducted by the inventors as named herein that optimal bathing conditions of substrate 200 are different depending upon such the minimal film thickness.

Some experimental results are shown in Table below, including results of void evaluation for plating film-formed substrates and buried film thickness uniformity evaluation.

TABLE

| | | Void | | Burying Uniformity | |
|---|---|---|---|---|---|
| | Entry | Evaluation | | Evaluation | |
| Case# | Conditions | t ≦3 nm | t >3 nm | t ≦3 nm | t >3 nm |
| (1) | Plating Vol. | Good | Good | 0.7 | 0.7 |
| | Appln | | | | |
| | No Sub. | | | | |
| | Cooling | | | | |
| (2) | No Vol. Appln | NG | NG | 1 | 1 |
| | No Sub. | | | | |
| | Cooling | | | | |
| (3) | No Vol. Appln | NG, but | Good | 1 | 1 |
| | Sub. Cooled | better | | | |
| | | than (2) | | | |
| (4) | Low Vol. | Good | Good | 0.9 | 0.9 |
| | Appln Sub. | | | | |
| | Cooled | | | | |

Note that in the table above, “t” is the minimum seed film thickness.

As apparent from the table, when letting it come into contact with the plating solution 670 while applying a voltage thereto for the purpose of seed dissolution prevention, the film is unintentionally different in buried state between a central portion of the substrate 200 and its edge portion to be first solution-contacted. In light of this fact, here, the burying uniformity was evaluated while using as a parameter a specific value which evaluates the buried state of the center part in case the first solution-contacted edge is 1. It is also apparent from FIG. 7 that it is difficult to form by sputtering the intended film on the sidewall. Thus, voids are readily occurrable at the sidewall. For void evaluation, sidewall void observation was done by cross-section scanning electron microscopy (SEM). The case of no voids being found is indicated by “Good,” whereas the case of voids found is “NG.” The entry conditions used are four kinds of conditions for comparison as will be presented below. The minimum thickness of seed film 250 also was varied for comparison.

In the condition (1), when dipping the substrate 200 into the plating solution 670 of plating bath 650, let it come into contact with the plating solution 670 while at the same time applying a voltage to the seed film 250 in order to prevent unwanted dissolution thereof. The voltage here is the same as a voltage to be actually used for plating. The resultant plating current can sometimes vary in magnitude during plating. In view of this, a specific voltage is applied which permits a plating current to flow at the beginning of a plating process. In other words, the current density during plating is set to 3 milliamperes per square centimeter (mA/cm²) or greater, and the voltage applied was set to ensure that the current density at a entry portion becomes 3 mA/cm² or above. No substrate cooling is performed.

In the condition (2), when dipping the substrate 200 into the plating solution 670 of plating bath 650, let it come into contact with the plating solution 670 in the absence of voltage application to the seed film 250. The substrate cooling is not performed.

With the condition (3), when dipping the substrate 200 in the plating solution 670 of plating bath 650, let it come into contact with the plating solution 670 in the absence of voltage application to the seed film 250. The above-noted substrate cooling is carried out to control the substrate temperature to stay at 10° C.

In the condition (4), when dipping the substrate 200 in the plating solution 670 of plating bath 650, let it come into contact with the plating solution 670 while at the same time applying a voltage to the seed film 250 in order to prevent seed dissolution. The voltage applied here is lower in potential than the plating startup voltage for actual use during plating. This applied voltage is designed here to force the current density at the time the entire surface of substrate 200 is put into the plating bath 650 to be equal to or less than one-half (½) of the current density during plating-typically, 0 to 1.5 mA/cm². The substrate cooling is performed so that the substrate temperature is controlled to stay at 10° C.

Comparison was done under these conditions (1) to (4) to reveal, by the void evaluation, the fact that the voltage application at the time of entry is essential to the suppression of unwanted void production in case the minimum thickness t of the seed film 250 is less than or equal to 3 nm. However, it was also revealed that as in the condition (1), the plating voltage application results in the substrate being less in uniformity between its central and peripheral portions—that is, the opening is buried at its center with the film having a thickness of mere 70% of the intended thickness even at a time point at which the peripheral portion of substrate has completely been buried. In contrast, as in the conditions (2) and (3), in case the voltage application at the time of entry is not performed, the buried-film thickness uniformity is attained; however, sidewall voids take place undesirably. With the condition (3), the frequency of void creation was lowered; thus, it has been demonstrated that the substrate cooling exhibited appreciable effects in suppression of seed-film dissolution. It has also been affirmed that the both sidewall void suppression and the buried-film uniformity were achieved by lessening the entry voltage while simultaneously cooling the substrate as in the condition (4).

Note here that although it appears that Cu dissolution does not take place with application of a voltage that forces the current density at the entry time to become 0 mA/cm², the reality is that dissolution reaction and deposition/separation reaction are in the state of equilibrium. Thus it is difficult to prevent dissolution of a thin film of seed film 250 as far as the substrate 200 is set at room temperatures. In contrast, this embodiment is arranged to cool the substrate 200 so that it is possible to reduce the dissolution rate even at 0 mA/cm², thereby making it possible to achieve the intended burying without creation of voids. Further, setting the current density at the entry time to be equal to or less than ½ of the current density during plating permits the film fabrication rate of a part of the substrate that was first brought into contact with the solution in the entry event to be also half-reduced or less. Thus it is possible to improve the buried-film thickness uniformity.

In case the minimum thickness t of the seed film 250 is greater than 3 nm, it has been affirmed that even in the lack of voltage application to the substrate 200 when its entry, the substrate cooling or “refrigeration” makes it possible to achieve the sidewall void suppression and the buried-film uniformity at a time. Thus it is possible to offer sufficient effects even with the substrate cooling alone, although it somewhat depends on the generation of the wiring rule of semiconductor devices.

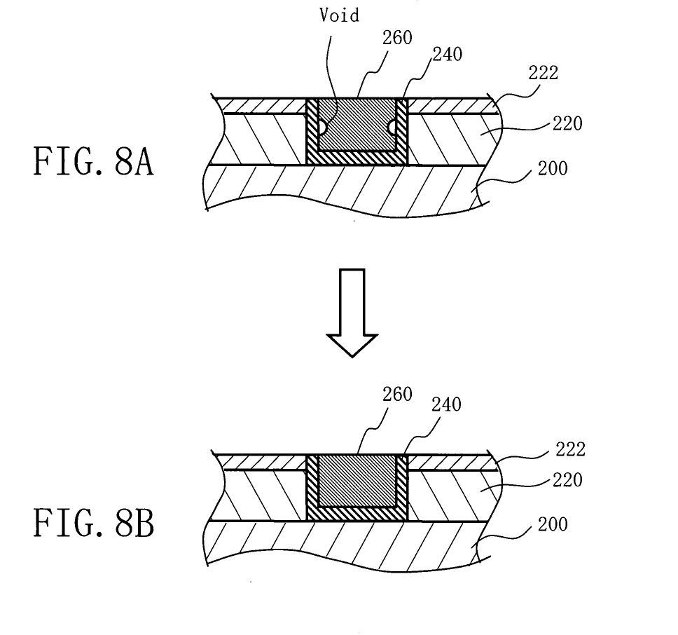

The effect of substrate cooling in this embodiment will be described in detail with reference to FIGS. 8A and 8B. As shown in FIG. 8A, when the substrate cooling is not performed, unwanted voids are created on the sidewall of an opening due to appreciable disappearance of Cu layer thereon. This is avoidable by entering the substrate 200 while simultaneously applying a voltage thereto. Unfortunately, this approach accompanies the risk of degradation of buried-film thickness uniformity. In contrast, as stated previously, entering the substrate 200 while controlling its temperature to stay at a low temperature serves to suppress unwanted dissolution of Cu layer prior to the plating as shown in FIG. 8B, thereby to make it possible to prevent failure of segregation or precipitation due to the Cu layer disappearance appreciably occurring on the opening sidewall. This makes it possible by potentially lowering the applied voltage to alleviate the difference in plating rate between the substrate peripheral part and center part, which has been controversial in the prior art method of entering the substrate with simultaneous voltage application thereto.

As apparent from the foregoing, this embodiment is capable of suppressing seed-film dissolution. This makes it possible to suppress both the failure of precipitation of an electro-plated film and the production of defects therein.

### Embodiment 2

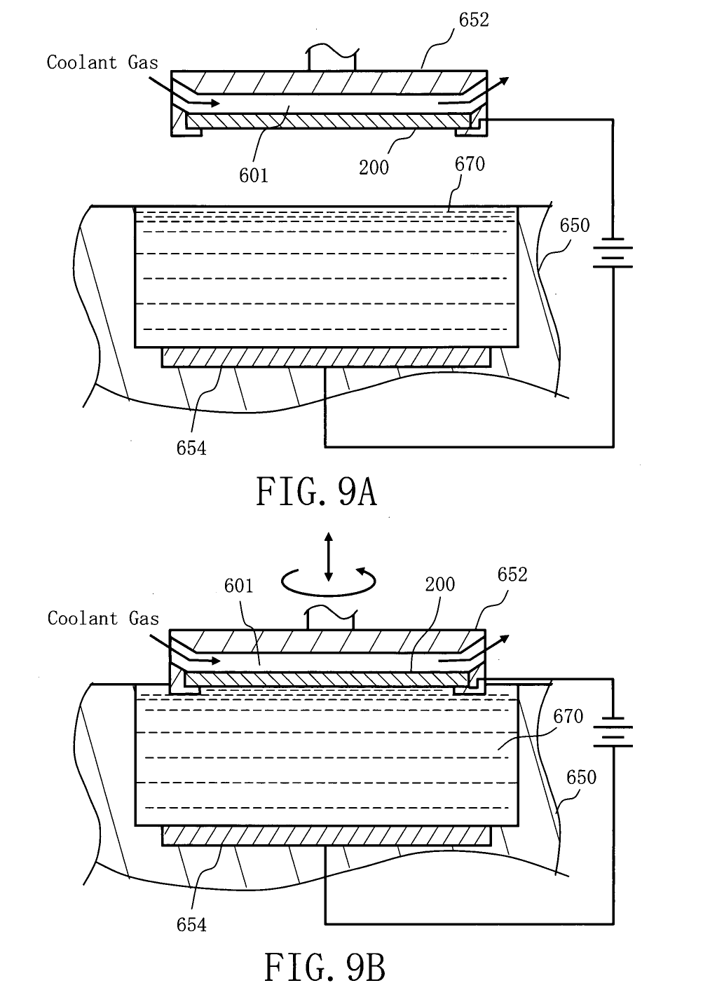

A substrate entry technique in accordance with another embodiment of this invention will be described with reference to FIGS. 9A and 9B. While the previous embodiment is arranged so that the substrate 200 is cooled at the waiting position shown in FIG. 4 prior to its entry into the plating bath 650 and the substrate cooling is stopped at the time the substrate 200 is dipped into the plating solution 670 in plating bath 650, the embodiment as discussed herein is similar thereto in that a chosen coolant gas is supplied to flow on the back surface of substrate 200 prior to its entry into the plating bath 650 as again shown in FIG. 9A and is different therefrom in that the substrate 200 is dipped into plating bath 650 while simultaneously cooling substrate 200 as shown in FIG. 9B. With such an arrangement, it is possible to further enhance the cooling effect. This substrate cooling may be continuously performed even in the process of actual plating when a need arises.

With the feature of the continuous substrate cooling during plating, it becomes possible to suppress or minimize unintentional temperature rise-up of the plating solution and a wafer being processed even in cases where the voltage is applied to cause the current density to stay at 80 mA/cm² or above.

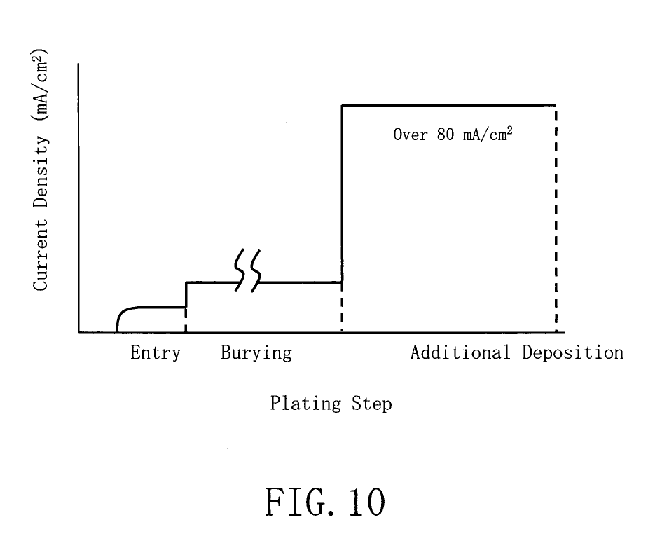

One example of a technique for performing plating at a plurality of levels of current density will be described with reference to FIG. 10. In standard plating processes, it is performed to use multiple steps. For instance, the step of burying Cu film 260 to fill the opening 150 uses a predetermined current density as optimized for such burying. At the step for additional film deposition after every pattern has been buried, plating is performed with different current density higher than that during burying. Using such higher current density results in an increase in film forming rate, which makes it possible to improve process throughputs. Incidentally in the prior art, the upper limit of the current density was restricted in view of the fact that the plating rate exceeds the rate of Cu ion feed from the plating solution 670 or in a viewpoint that the plating solution 670 and substrate 200 increase in temperature due to Joule heating. In terms of the temperature risêup of plating solution 670 and substrate 200, it has been difficult in the prior art to use current density values of more than 80 mA/cm². In this embodiment the current density of 80 mA/cm² or greater is used under the condition that Cu ions are supplied in a sufficiently accelerated way. To enable this, substrate cooling is performed. In other words, the substrate 200 is cooled down at least at the additional deposition step. A cooling scheme thereof is to force a gas to flow on the back surface of substrate 200 in the way as shown in FIG. 9. This suppresses Joule heating and thus makes it possible to use the high current density of 80 mA/cm² or more, which has never been used in the prior art. Setting the current density for additional film deposition to 80 mA/cm² or above enables promotion of grain growth of Cu film 260. Furthermore, it has been affirmed to attain improved reliability when compared to interconnect wires that are formed at low current density in case annealing is applied at a later process step. By performing the in-situ substrate cooling in this way, it becomes possible to increase the current up to a higher level that has traditionally been inapplicable due to increase in plating solution temperature, thereby enabling achievement of large grain sizes and also improvement of the reliability. Regarding the current density for use at the entry step of dipping the substrate 200 into the plating bath 650 while at the same time cooling the substrate 200, it is the same as that in the first embodiment stated supra.

Although several embodiments have been explained above while referring to some practical examples, this invention should not be limited only to these practical examples. While in the embodiments the low-k film 220 is used as a dielectric film, this is not the one that limits the invention, and no specific problems occur even in cases where other dielectric materials are used. For example, a silicon oxide film (SiO₂) is employable. Additionally, although in the above-noted embodiments a gas is used to cool the substrate, this is not the one that limits the invention and a liquid may alternatively be used as far as the plating apparatus is designed so that the liquid does not leak from the back surface to the top surface of substrate 200. The substrate 200's back surface is not always cooled directly and may alternatively be cooled indirectly. Similar cooling effects are also obtainable by mainly lowering the temperature of an atmosphere near or around the wafer holder 652 in the plating apparatus. Although the embodiments are aimed at formation of damascene-structure interconnect wires, these may be replaced by dual-damascene interconnect wires with achievement of similar advantages. In particular, the principles of this invention are adaptable for use in the process of burying Cu material into via holes in the manufacture of dual damascene interconnect wires.

Additionally, regarding the film thickness of ILD film along with the size, shape and number of the openings, these may be adequately designed on a case-by-case basis in accordance with the needs for semiconductor integrated circuits and/or various types of semiconductor circuit elements.

Any other similar fabrication methods of semiconductor device including electronic components which comprise the elements of this invention and which are design-alterable case-by-case by those skilled in the art should be interpreted to fall within the scope of this invention.

Although those processes as ordinarily used in the semiconductor industry, such as photolithography and pre- and post-cleaning processes, are not specifically described herein, it readily occurs to technicians in this art that such processes are also included in the fabrication method of the invention.

Additional advantages and modifications will readily occur to those skilled in the art. Therefore, the invention in its broader aspects is not limited to the specific details and representative embodiments as shown and described herein. Accordingly, various modifications may be made without departing from the spirit and scope of the general inventive concepts as defined by the appended claims and equivalents thereto.

What is claimed is:

1. A method for fabricating an electronic component, comprising:
forming a seed film above a base body;
cooling said seed film; and
putting the cooled seed film into a plating solution to perform electro-plating with said seed film being as a cathode.

2. The method according to claim 1, wherein a gas is used to cool a back surface of said base body to thereby cool said seed film.

3. The method according to claim 2, wherein said gas is any one of a nitrogen gas and an air.

4. The method according to claim 1, wherein when performing said electro-plating, said seed film is dipped into the plating solution while simultaneously applying a voltage to said seed film.

5. The method according to claim 4, wherein during dipping said seed film into said plating solution, said seed film is applied a lower voltage than a start-up voltage for starting electro-plating after the dipping into said plating solution.

6. The method according to claim 5, wherein the voltage as applied when dipping into said plating solution has its current density less than or equal to one-half of a current density of a current to be flown upon start-up of said electro-plating.

7. The method according to claim 5, wherein when performing said electro-plating, a plurality of steps different in current density from each other are performed.

8. The method according to claim 1, wherein said base body has an opening formed therein, and wherein said electro-plating is used to perform filling of a copper-containing film in the opening and additional deposition of said copper-containing film above said base body.

9. The method according to claim 8, wherein the additional deposition is performed while letting said base body be cooled.

10. The method according to claim 9, wherein during the additional deposition of said copper-containing film, electro-plating is performed at a current density of 80 milliamperes per square centimeter (mA/cm²) or greater.

11. The method according to claim 9, wherein said base body is cooled by cooling a back surface of said base body using a gas.

12. The method according to claim 11, wherein said gas is any one of a nitrogen gas and an air.

13. A method for fabricating an electronic component, comprising:
forming an opening in a base body;
burying a copper-containing film in the opening; and
permitting additional deposition of said copper-containing film above said base body with the opening filled with said copper-containing film while cooling said base body.

14. The method according to claim 13, wherein the burying and the additional deposition are performed by an electro-plating technique.

15. The method according to claim 14, wherein during the additional deposition of said copper-containing film, electro-plating is performed with a current density higher than that during burying said copper-containing film.

16. The method according to claim 14, wherein during the additional deposition of said copper-containing film, electro-plating is performed at a current density of 80 mA/cm² or greater.

17. The method according to claim 14, wherein said base body is dipped in a plating solution while letting said base body be cooled.

18. The method according to claim 13, wherein a back surface of said base body is cooled by use of a gas.

19. The method according to claim 18, wherein said gas is any one of a nitrogen gas and an air.

20. The method according to claim 13, wherein the burying results in formation of a copper interconnect wire of a semiconductor device.
